(19) United States
(12) Patent Application Publication
(10) Pub. No.: US 2021/0167123 A1
(43) Pub. Date: Jun. 3, 2021

(54) MICRO LED DISPLAY DEVICE

(71) Applicant: YingLight Technology Co. Ltd., Changhua County (TW)

(72) Inventors: PING-YU TSAI, Yunlin (TW); CHUNG-CHING CHEN, Pingtung County (TW)

(21) Appl. No.: 17/170,852

(22) Filed: Feb. 8, 2021

Related U.S. Application Data
(63) Continuation-in-part of application No. 16/136,233, filed on Sep. 19, 2018, now abandoned.

(30) Foreign Application Priority Data
Feb. 2, 2018 (TW) 107103892

(51) Int. Cl. H01L 27/15; G02B 5/20; H01L 33/50; H01L 33/58; G02B 5/30; H01L 25/075

(52) U.S. Cl. CPC H01L 27/156; G02B 5/201; H01L 25/0753; H01L 33/58; G02B 5/3025; H01L 33/507

(57) ABSTRACT

A micro LED display device includes a micro LED array, a light enhancing layer, a color filter and a polarizer. The micro LED array includes a plurality of micro LEDs, wherein each of the micro LEDs is independently controlled to emit a light. The light enhancing layer is located above the micro LED array, wherein the light enhancing layer includes a plurality of quantum dots. The color filter is located above the light enhancing layer, wherein properties of the light of each of the micro LEDs is converted by each of the quantum dots thereby projecting a plurality of sub-pixel units in the color filter. The polarizer is located above the color filter.

### RELATED APPLICATIONS

This application is a continuation of Ser. No. 16/136,233, entitled “MICRO LED DISPLAY DEVICE” (now Pub. No. US 2019/0245006 A1) filed Sep. 19, 2018, which is herein incorporated by reference.

### BACKGROUND

### Technical Field

The present disclosure relates to a display device. More particularly, the present disclosure relates to a micro LED display device.

### Description of Related Art

Recently, a display device has been rapidly developed as an important human-machine interface. A portable electronic device, a computer or a television can represent complicated messages through the display device.

Owing to the demands on the large visible area, compact volume and low energy consumption, a liquid crystal display (LCD) device is getting more popular and has become a mainstream. A conventional LCD device 100 is shown in FIG. 1. The LCD device 100 includes, from bottom to top, a backlight module 111, a first polarizer 112, a first substrate 113, a transistor layer 114, a first electrode 115, a liquid crystal layer 116, a second electrode 117, a color filter 118, a second substrate 119 and a second polarizer 120. The operation mechanism of the LCD device 100 is then briefly described. The liquid crystal molecules in the liquid crystal layer 116 are twisted when a voltage is applied. One or more transistors in the transistor layer 114 is/are used to control the twisted direction of the liquid crystal molecules and are functioned as a light switch. Furthermore, lights emitted from the backlight module 111 are passed through the first polarizer 112 and the second polarizer 120 for generating different polarized direction lights to incorporate with the twisted directions of the liquid crystal molecules to control the brightness variation to form a gray scale. An image with a full color can be formed by combining a plurality of pixels. Each of the pixels consists of a plurality of sub-pixel units 118a in the color filter 118. However, the formation of the sub-pixel units 118a is determined by each transistor in the transistor layer 114, which control the luminance of the backlight module 111. Furthermore, an alignment film can be disposed on the first substrate 113 and the second substrate 119 for aligning the liquid crystal molecules. A voltage can be applied to the transistor layer 114 through the first electrode layer 115 and the second electrode 117.

However, the power efficiency and the brightness (contrast) of such kind of LCD device 100 is low because only few lights emitted from the backlight module 111 can pass through the liquid crystal layer 116. Furthermore, the manufacturing processes of the transistor layer 114 are complicated thereby increasing the manufacturing cost. OLED device has been reached to the market as an alternative of the LCD device 100. The OLED device has larger viewing angle than the conventional LCD device 100, however, issues such as light color flashing and light color decay still exist due to the material properties of the organic component, thus the lifetime of the OLED device is dramatically reduced.

Therefore, there is a need to develop a display device having high power efficiency, large viewing angle and long lifetime.

### SUMMARY

According to one aspect of the present disclosure, a micro LED display device is provided. The micro LED display device includes a micro LED array, a light enhancing layer, a color filter and a polarizer. The micro LED array includes a plurality of micro LEDs, wherein each of the micro LEDs is independently controlled to emit a light. The light enhancing layer is located above the micro LED array, wherein the light enhancing layer includes a plurality of quantum dots. The color filter is located above the light enhancing layer, wherein properties of the light of each of the micro LEDs is converted by each of the quantum dots thereby projecting a plurality of sub-pixel units in the color filter. The polarizer is located above the color filter.

In one example, the quantum dots convert a color of the light of each of the micro LEDs of the micro LED array.

In one example, the quantum dots reduce a full width at half maximum of the light of each of the micro LEDs of the micro LED array.

In one example, the quantum dots increase conversion efficiency of the light of each of the micro LEDs passed through the light enhancing layer.

In one example, the micro LED display device includes an electrode layer, wherein the electrode layer drives the micro LED array to emit lights.

In one example, the micro LED display device further includes a first substrate and a second substrate, wherein the first substrate is located between the light enhancing layer and the color filter, and the second substrate is located between the color filter and the polarizer.

In one example, the color filter includes a light-absorptive material.

In one example, each of the sub-pixel units is corresponded to a red color, a green color or a blue color.

In one example, the light of each of the micro LEDs includes a red color, a green color or a blue color.

In one example, a color of the light of each of the micro LEDs is different or identical.

In one example, a color of each of the sub-pixel units is corresponded to a color of the light of each of the micro LEDs.

In one example, each of the sub-pixel units in the color filter is departed by a mask.

In one example, each of the micro LEDs is aligned correspondingly to each of the sub-pixel units.

In one example, the sub-pixel units in the color filter are aligned in a linear shape, a square shape, a triangle shape or a mosaic shape.

According to another aspect of the present disclosure, a micro LED display device is provided. The micro LED display device includes a micro LED array and a color filter. The micro LED array includes a plurality of micro LEDs, wherein each of the micro LEDs is independently controlled to emit a light. The color filter includes a plurality of quantum dots and is located above the micro LED array, wherein properties of the light of each of the micro LEDs is converted by each of the quantum dots thereby projecting a plurality of sub-pixel units in the color filter.

In one example, the micro LED display device further includes a polarizer located above the color filter.

In one example, the quantum dots convert a color of the light of each of the micro LEDs of the micro LED array.

In one example, the quantum dots reduce a full width at half maximum of the light of each of the micro LEDs of the micro LED array.

In one example, the quantum dots increase conversion efficiency of the light of each of the micro LEDs passed through the color filter.

### BRIEF DESCRIPTION OF THE DRAWINGS

The present disclosure can be more fully understood by reading the following detailed description of the embodiment, with reference made to the accompanying drawings as follows:

FIG. 1 is a schematic view showing a conventional LCD device;

FIG. 2 is a schematic view showing a micro LED display device according to one embodiment of the present disclosure;

FIG. 3 is a schematic view showing a micro LED display device according to one embodiment of the present disclosure; and

FIG. 4 is a schematic view showing a micro LED display device according to one embodiment of the present disclosure.

### DETAILED DESCRIPTION

Micro LEDs are regarded as the next-generation display technology due to its superior properties such as high contrast, high efficiency, high resolution, high response time, etc. Furthermore, a micro LED display device has high color saturation and rapid frame rate and is particularly suitable for next-generation advanced applications (e.g. ultrahigh-definition TVs, micro projectors). An elementary type of micro LED display device only utilizes RGB LEDs to generate a full color image. However, this kind of micro LED display device has disadvantages due to natural material properties of RGB LEDs, such as low efficiency of green LEDs and seriously reduced EQE (External Quantum Efficiency) of red LEDs when LED chip size shrinks down to below 20 μm. Furthermore, owing to the different materials properties of different color LEDs, mismatch in electrical properties occurred thereby resulting in difficulties on integrating these different LEDs. Accordingly, the present disclosure provides improvements of such kind of micro LED display device.

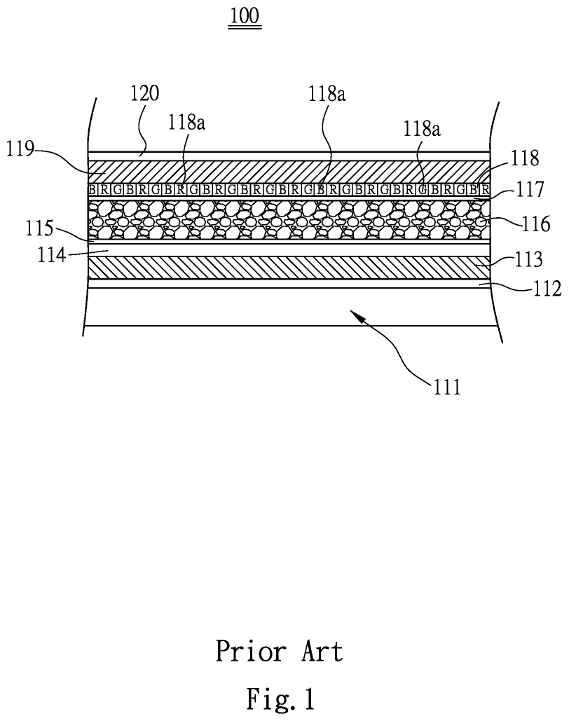

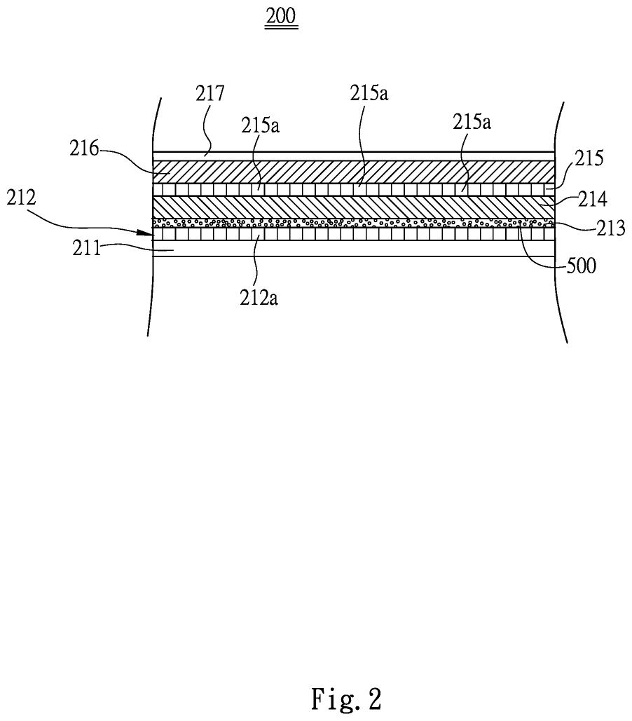

FIG. 2 is a schematic view showing a micro LED display device 200 according to one embodiment of the present disclosure. The micro LED display device 200 includes a micro LED array 212, a light enhancing layer 213, a color filter 215 and a polarizer 217. The light enhancing layer 213 is located above the micro LED array 212; the color filter 215 is located above the light enhancing layer 213; and the polarizer 217 is located above the color filter 215. The micro LED display device 200 also includes a first substrate 214 and a second substrate 216. The first substrate 214 is located between the light enhancing layer 213 and the color filter 215. The second substrate 216 is located between the color filter 215 and the polarizer 217. The micro LED display device 200 can further include an electrode layer 211. The electrode layer 211 can be located under the micro LED array 212 for electrically driving the micro LED array 212 to emit lights. The light enhancing layer 213 includes a plurality of quantum dots 500. Properties of the light emitted from each of the micro LEDs 212a is converted by each of the quantum dots 500 thereby projecting a plurality of sub-pixel units 215a in the color filter 215. The mechanism of forming the sub-pixel units 215a of the micro LED display device 200 of the present disclosure is distinctly different from that of the conventional LCD device. Conventional LCD device is recognized as non-emissive display device owing to LC (Liquid Crystal) panel cannot emit light, the required light source is provided by using an extra backlight module. The micro LED display device 200 of the present disclosure is recognized as emissive display device owing to micro LEDs 212a can emit light itself, without requiring any extra backlight source. Accordingly, in a non-emissive LCD device 100 as in FIG. 1, the LC panel includes a plurality of pixels where each of the pixels consists of RGB sub-pixel units, and each RGB sub-pixel unit is addressed independently by a thin-film transistor (TFT), which regulates the luminance transmittance from the backlight module 111. In contrast, in the emissive micro LED display device 200 as in the present disclosure, micro LEDs 212a both directly serves as sub-pixel units 215a and light source. Therefore, backlight module 111 in LCD device 100 as in FIG. 1 doesn't participate in the formation of the sub-pixel units 118a, each sub-pixel unit 113a is formed by an unit TFT transistor in the transistor layer 114.

The operation mechanism of the micro LED display device 200 is then described. The micro LED array 212 includes a plurality of micro LEDs 212a which are aligned in order. Each of the micro LEDs 212a is electrically driven by the electrode layer 211, and can be independently controlled to emit a light. The electrode layer 211 can be made from conductive materials (metal or other materials), and can provide the required electric power. The lights emitted from the micro LED array 212 pass through the light enhancing layer 213 located above. The micro LED 212a is an inorganic LED, material such as InGaN is commonly used for blue and green LEDs, and material such as AlGaInP is commonly used for red LEDs. In the present disclosure, the light enhancing layer 213 may has many functionalities due to a plurality of quantum dots 500 are spread in the light enhancing layer 213.

Quantum dots 500 are small semiconductor crystals with sizes down to nanoscale. Their properties are vastly different from bulk semiconductors. The most striking characteristics of the quantum dots 500 are the tuneability of the semiconductor bandgap by varying their size and discrete energy levels (so-called quantum confinement effect). Furthermore, when applying quantum dots 500 in micro LED displays 200, narrow spectra can be obtained owing to their narrow emission line width (e.g. full width at half maximum (FWHM) is about 20 to 30 nm for Cdse and InP based quantum dots). High color saturation is obtained at the extrema by narrow spectra, which cover greater than 90% of the strictest Rec. 2020 color gamut standard. The narrow linewidths of the quantum dots 500 also enable them to form viable active elements of micro LEDs in high-definition displays.

In addition to reduce a full width at half maximum (FWHM) of the light of each of the micro LEDs 212a of the micro LED array 212, the quantum dots 500 in the present disclosure can also convert a color of the light of each of the micro LEDs 212a of the micro LED array 212. The quantum dots 500 also increase conversion efficiency of the light of each of the micro LEDs 212a passed through the light enhancing layer 213. The emergence of quantum dot 500 has benefits of high photoluminescence quantum yield, high photostability, solution processability, low fabrication cost and color tuneability, thereby providing a powerful full-color solution for high-definition micro LED display devices.

The color filter 215 disposed above the light enhancing layer 213 is used for enhancing color saturation. It has been known that a full color image is generated by combining a plurality of smallest addressable elements (so called pixels), and each of the pixels includes a plurality of sub-pixel units 215a. In FIG. 2, each of the micro LEDs 212a generates a sub-pixel units 215a, and projects the sub-pixel unit 215a in the color filter 215. A pixel can be formed by combining the sub-pixels 215a. For generating a full color image, the color of each of the micro LEDs 212a can be different or identical. For example, in a three primary color system, the light of each of the micro LEDs 212a is a red color, a green color and a blue color separately, therefore each of the sub-pixel units 215a is corresponded to a red color, a green color and a blue color separately and are combined to form a pixel. In a four primary color system, the light of each of the micro LEDs 212a is a red color, a green color, a blue color and a yellow color separately, therefore each of the sub-pixel units 215a is corresponded to a red color, a green color, a blue color and a yellow color separately and are combined to form a pixel. In a six primary color system, the light of each of the micro LEDs 212a is a red color, a green color, a blue color, a cyan color, a purple color and a yellow color separately, therefore each of the sub-pixel units 215a is corresponded to a red color, a green color, a blue color a cyan color, a purple color and a yellow color separately and are combined to form a pixel. In the aforementioned embodiments, each of the micro LEDs 212a emits different color, and the color of each of the sub-pixel units 215a is corresponded to the color of the light of each of the micro LEDs 212a. A better color saturation and color reproduction can be achieved while using more sub-pixel units 215a with different colors. Furthermore, an alignment form of the sub-pixel units 215a also has influence on the color saturation. In other word, the sub-pixel units 215a can be aligned in a linear shape, a square shape, a triangle shape or a mosaic shape fir obtaining different color saturation. In the situation that each micro LED 212a has the same color, the quantum dots 500 of the present disclosure can be used for convert the color of the light of each of the micro LEDs 212a for generating a full color image. For example, when each of the micro LEDs 212a emit the same blue color, for generating three primary color (RGB), three micro LEDs 212a are used in corporation with three types of colored quantum dots 500. A first type of quantum dot 500 is used to convert blue color into red color. A second type of quantum dot 500 is used to convert blue color into green color. A third type of quantum dot 500 is used to generate the same blue color, but enhances the properties of the light (e.g. reduces emission line width, increases quantum efficiency, etc.). Furthermore, the color filter 215 also has light-transmission regions, and each of the light-transmission regions is aligned correspondingly to each of the micro LEDs 212a. Each of the light-transmission regions can allow the light emitted from each of the micro LEDs 212a to pass through. Since the light with various colors of each of the micro LEDs 212a passes through the light enhancing layer 213 and then passes through each of the light-transmission regions of the color filter 215, the light passes through the color filter 215 can still keep its narrow line width (FWHM) resulted from the quantum dots 500 in the light enhancing layer 213, therefore color saturation can be enhanced.

Each micro LED 212a will emit light in both the upward and downward directions. To utilize downward light, the electrode layer 211 may include a reflective electrode deposited at the bottom of each micro LED 212a. However, such reflective electrode also reflects or scatters the incident ambient light, which could degrade the Ambient Contrast Ratio (ACR). For solving this issue, one strategy is to adopt tiny LED chips to reduce the aperture ratio and cover the non-emitting area with a mask (black matrix) to absorb the reflected or scattered ambient light. Another strategy to suppress the reflected or scattered ambient light is using a color filter 215 having light-absorptive material to absorb unwanted lights.

A polarization angle and a polarization direction of a light can be adjusted when the light passes through the polarizer 217. In high luminance situation (i.e., the micro LED array 212 emits ultrahigh brightness), a circular polarizer 217 is commonly registered above the color filter 215 to block the reflected ambient light from the bottom electrode layer 211 in order to suppress the ambient light reflection from the bottom electrode layer 211. The polarizer 217 may be removed when the color filter 215 includes light-absorptive material (absorptive color filter). However, in the embodiment of FIG. 2, while the color filter 215 is an absorptive color filter, the ambient light reflection from the bottom electrode layer 211 can be further reduced by the corporation of the polarizer 217 and the color filter 215.

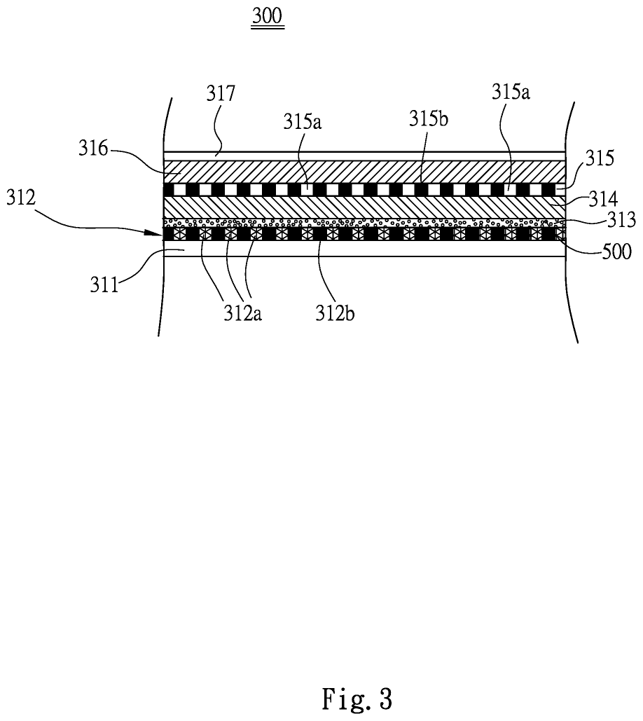

FIG. 3 is a schematic view showing a micro LED display device 300 according to one embodiment of the present disclosure. In FIG. 3, similar as the micro LED display device 200 in FIG. 2, the micro LED display device 300 includes an electrode layer 311, a micro LED array 312, a light enhancing layer 313, a first substrate 314, a color filter 315, a second substrate 316 and a polarizer 317. The light enhancing layer also includes a plurality of quantum dots 500. The details of the functions and the alignment order of each layer are similar as that in FIG. 2, and are not addressed herein. The difference between the micro LED display device 200 and the micro LED display device 300 is that each of the sub-pixel units 315a in the micro LED display device 300 is departed by a mask 315b. The mask 315b can be used to block a scattered or reflected ambient light for preventing the interference. The mask 315b can be made of black materials to form a so-call black matrix. A plurality of masks 312b are also located between each of the micro LEDs 312a. Furthermore, each of the sub-pixel units 315b is aligned from each other, and each of the micro LEDs 312a is aligned correspondingly to each of the sub-pixel units 315b.

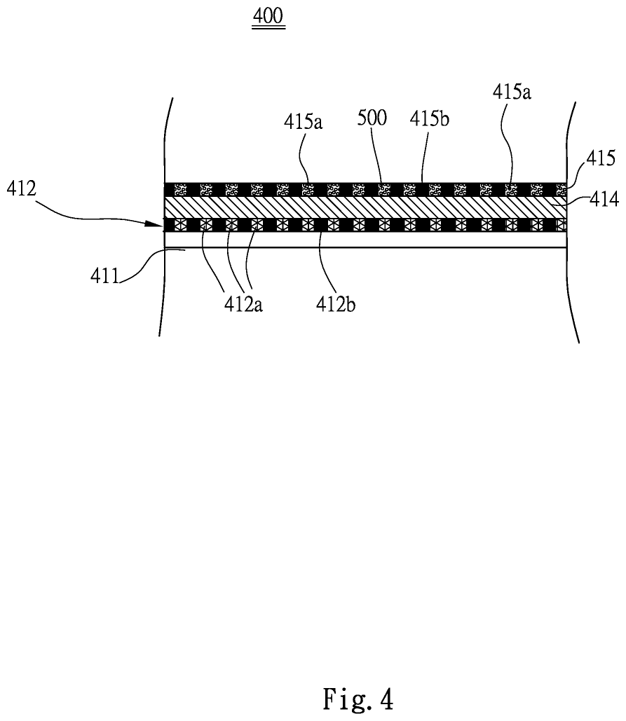

FIG. 4 is a schematic view showing a micro LED display device 400 according to one embodiment of the present disclosure. The micro LED display device 400 includes an electrode layer 411, a micro LED array 412, a substrate 414 and a color filter 415. The color filter includes a plurality of quantum dots 500. Mask 312b, 315b is also used for reducing the reflected or scattered ambient light. In FIG. 4, the light enhancing layer 313 in FIG. 3 is removed. In FIG. 2 and FIG. 3, the light enhancing layer 213, 313 filled with quantum dots 500 is used for increasing the light performance. However, in FIG. 2 and FIG. 3, the light enhancing layer 213, 313 located above the light source (micro LED array 212, 312) may possibly absorbs the light emitted from the micro LEDs 212a, 312a, thus the light conversion efficiency may be decreased, resulting in the decrease of the color gamut. For further improving the light performance, the color quantum dots 500 are emerged into to the color filter 415, as shown in FIG. 4. Furthermore, the volume of the micro LED display device 400 can be further reduced for obtaining a more compact size.

In the micro LED display device 200, 300, 400 of the present disclosure, the emitted light is provided by the micro LEDs 212a, 312a, 412a of the micro LED array 212, 312, 412, and the micro LEDs 212a, 312a, 412a are also serve as sub-pixel units 215a, 315a, 415a. The mechanism of generating full color image of such micro LED display device 200, 300, 400 is significantly different from the conventional LCD device. Therefore, in the micro LED display device 200, 300, 400 of the present disclosure, extra backlight module is not required, therefore the manufacturing cost can be reduced. Furthermore, the micro LED display device 200, 300, 400 of the present disclosure also has higher power efficiency, wider viewing angle, longer lifetime and higher color gamut than the conventional LCD device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A micro LED display device comprising:
a micro LED array comprising a plurality of micro LEDs, wherein each of the micro LEDs is independently controlled to emit a light;
a light enhancing layer located above the micro LED array, wherein the light enhancing layer comprises a plurality of quantum dots;
a color filter located above the light enhancing layer, wherein properties of the light of each of the micro LEDs is converted by each of the quantum dots thereby projecting a plurality of sub-pixel units in the color filter; and
a polarizer located above the color filter.

2. The micro LED display device of claim 1, wherein the quantum dots convert a color of the light of each of the micro LEDs of the micro LED array.

3. The micro LED display device of claim 1, wherein the quantum dots reduce a full width at half maximum of the light of each of the micro LEDs of the micro LED array.

4. The micro LED display device of claim 1, wherein the quantum dots increase conversion efficiency of the light of each of the micro LEDs passed through the light enhancing layer.

5. The micro LED display device of claim 1, further comprising:
an electrode layer, wherein the electrode layer drives the micro LED array to emit lights.

6. The micro LED display device of claim 1, further comprising:
a first substrate and a second substrate, wherein the first substrate is located between the light enhancing layer and the color filter, and the second substrate is located between the color filter and the polarizer.

7. The micro LED display device of claim 1, wherein the color filter comprises a light-absorptive material.

8. The micro LED display device of claim 1, wherein each of the sub-pixel units is corresponded to a red color, a green color or a blue color.

9. The micro LED display device of claim 1, wherein the light of each of the micro LEDs comprises a red color, a green color or a blue color.

10. The micro LED display device of claim 9, wherein a color of the light of each of the micro LEDs is different or identical.

11. The micro LED display device of claim 1, wherein a color of each of the sub-pixel units is corresponded to a color of the light of each of the micro LEDs.

12. The micro LED display device of claim 1, wherein each of the sub-pixel units in the color filter is departed by a mask.

13. The micro LED display device of claim 1, wherein each of the micro LEDs is aligned correspondingly to each of the sub-pixel units.

14. The micro LED display device of claim 1, wherein the sub-pixel units in the color filter are aligned in a linear shape, a square shape, a triangle shape or a mosaic shape.

15. A micro LED display device comprising:
a micro LED array comprising a plurality of micro LEDs, wherein each of the micro LEDs is individually controlled to emit a light; and
a color filter located above the micro LED array, wherein the color filter comprises a plurality of quantum dots, and properties of the light of each of the micro LEDs is converted by each of the quantum dots thereby projecting a plurality of sub-pixel units in the color filter.

16. The micro LED display device of claim 15, further comprising:
a polarizer located above the color filter.

17. The micro LED display device of claim 15, wherein the quantum dots convert a color of the light of each of the micro LEDs of the micro LED array.

18. The micro LED display device of claim 15, wherein the quantum dots reduce a full width at half maximum of the light of each of the micro LEDs of the micro LED array.

19. The micro LED display device of claim 15, wherein the quantum dots increase conversion efficiency of the light of each of the micro LEDs passed through the color filter.
